(19) United States
(12) Patent Application Publication
(10) Pub. No.: US 2026/0175579 A1
(43) Pub. Date: Jun. 25, 2026

(54) LIQUID-REPELLENT SUBSTRATE, AND INK JET HEAD AND PRODUCTION METHOD THEREFOR

(71) Applicant: CANON KABUSHIKI KAISHA, Tokyo (JP)

(72) Inventors: KOJI SASAKI, Chiba (JP); YOHEI MIYAUCHI, Tokyo (JP); JUNRI ISHIKURA, Tokyo (JP); TADAHIRO MIMURA, Kanagawa (JP)

(21) Appl. No.: 19/423,786

(22) Filed: Dec. 17, 2025

(30) Foreign Application Priority Data
Dec. 20, 2024 (JP) 2024-225101

(51) Int. Cl. B41J 2/14; B41J 2/16; C23C 16/32

(52) U.S. Cl. CPC B41J 2/1433; B41J 2/1606; B41J 2/1642; C23C 16/325

(57) ABSTRACT

An ink jet head including an orifice plate. The orifice plate includes a substrate, a liquid-repellent film formed on an outermost surface of the substrate on an ink ejection surface side, and an underlying film formed between the substrate and the liquid-repellent film. The underlying film contains a silicon atom (Si), a carbon atom (C), and an oxygen atom (O). The liquid-repellent film forms a siloxane bond with the underlying film. A maximum peak P of a binding energy of a Si2p orbital of a surface part of the underlying film measured by X-ray photoelectron spectroscopy satisfies formula (1): 102.9 (eV)<P≤104.0 (eV) (1).

### BACKGROUND

### Field of the Technology

The present disclosure relates to a liquid-repellent substrate including a liquid-repellent film, and to an ink jet head including a liquid-repellent film and a production method therefor.

### Description of the Related Art

As a device that ejects an ink (hereinafter referred to as “ink jet head”), there have been known a bubble jet (trademark) head that instantaneously vaporizes the ink through use of a heater to fly liquid droplets, a piezo jet head that propels liquid droplets through use of a piezoelectric element, and the like. In order to record a high-quality image through use of an ink jet head, it is required that ink droplets be ejected from ink ejection orifices with satisfactory straightness along a predetermined direction. However, when a liquid droplet residue adheres to an orifice plate surface on the periphery of the ejection orifices, ink droplets are dragged by the residue at the time of ejection of the ink droplets to cause deflection in an ejection direction, with the result that the ink droplets may fly out of the predetermined direction. In view of the foregoing, in order to suppress the adhesion of the liquid droplet residue on the periphery of the ink ejection orifices, there is a proposal of the arrangement of a liquid-repellent film on the periphery of the ink ejection orifices.

In International Publication No. WO 2020/144850, there is a disclosure of an ink jet head in which a liquid-repellent layer underlying film containing at least a silicon atom (Si) and a carbon atom (C) is arranged on an orifice plate (nozzle plate), and a liquid-repellent layer is formed by chemically bonding a silane coupling agent to the underlying film.

Meanwhile, in an ink jet head, the cleaning of an orifice plate with a wiper is performed in order to remove a liquid droplet residue, paper dust, and the like. Thus, the liquid-repellent layer (liquid-repellent film) is required to have sliding resistance in the cleaning operation in addition to ink resistance. In addition, when the silane coupling agent is bonded to the underlying film, silicon oxide is generally used as the underlying film, but as described in International Publication No. WO 2020/144850, an underlying film containing a silicon atom and a carbon atom may be used to improve the ink resistance. However, when the silane coupling agent is bonded to the underlying film containing a silicon atom and a carbon atom, there is a disadvantage in that a reaction rate in the formation of a Si—C bond is lower than that in the formation of a Si—O bond.

### SUMMARY

The inventors have found that the ability of a liquid-repellent film may be reduced by prolonged ink contact and sliding. The present disclosure is directed to providing a liquid-repellent substrate and an ink jet head each including a liquid-repellent film excellent in sliding resistance and ink resistance.

One aspect of a configuration according to the present disclosure is an ink jet head including an orifice plate, wherein the orifice plate includes: a substrate; a liquid-repellent film formed on an outermost surface of the substrate on an ink ejection surface side; and an underlying film formed between the substrate and the liquid-repellent film, wherein the underlying film contains a silicon atom (Si), a carbon atom (C), and an oxygen atom (O), wherein the liquid-repellent film forms a siloxane bond with the underlying film, and wherein a maximum peak P of a binding energy of a Si2p orbital of a surface part of the underlying film measured by X-ray photoelectron spectroscopy satisfies the following formula (1):

$$102.9 ( eV ) < P \leq 104. ( eV ) . \qquad ( 1 )$$

In addition, one aspect of the configuration according to the present disclosure is a method of producing an ink jet head, the method including the steps of: forming a substrate having an ejection orifice configured to eject an ink; forming an underlying film on an ink ejection surface side of the substrate, the underlying film containing a silicon atom (Si), a carbon atom (C), and an oxygen atom (O) so that atomic composition ratios (atomic %) thereof fall within the following respective ranges, and the underlying film having a maximum peak P of a binding energy of a Si2p orbital of a surface part thereof measured by X-ray photoelectron spectroscopy satisfying the following formula (1); and forming a liquid-repellent film on an ink ejection surface side of the underlying film:

$$102.9 ( eV ) < P \leq 104. ( eV ) ; \qquad ( 1 )$$

silicon atom: 19 atomic % to 26 atomic %;
carbon atom: 13 atomic % to 42 atomic %; and
oxygen atom: 39 atomic % to 61 atomic %.

In addition, one aspect of the configuration according to the present disclosure is a liquid-repellent substrate including: a substrate; a liquid-repellent film; and an underlying film arranged between the substrate and the liquid-repellent film, wherein the liquid-repellent film forms a siloxane bond with the underlying film, wherein the underlying film contains a silicon atom (Si), a carbon atom (C), and an oxygen atom (O), and wherein a maximum peak P of a binding energy of a Si2p orbital of a surface part of the underlying film measured by X-ray photoelectron spectroscopy satisfies the following formula (1):

$$102.9 ( eV ) < P \leq 104. ( eV ) . \qquad ( 1 )$$

Features of the present disclosure will become apparent from the following description of embodiments with reference to the attached drawings. The following description of embodiments is described by way of example.

### BRIEF DESCRIPTION OF THE DRAWINGS

FIG. 1A is a top view of an ink jet head.

FIG. 1B is a bottom view of the ink jet head.

FIG. 1C is a partial perspective view for illustrating a cross-sectional structure taken along the line A-A′.

FIG. 2 is a schematic sectional view for illustrating a typical configuration of an orifice plate having an ejection orifice.

FIG. 3 is an XPS spectrum of the surface part of an underlying film measured in each of Examples and Comparative Examples.

### DESCRIPTION OF THE EMBODIMENTS

An orifice plate (liquid-repellent member), an ink jet head, and the like according to embodiments of the present disclosure are described below with reference to the drawings. In the following description, the terms “liquid repellency,” “liquid-repellent film,” and “liquid-repellent member” are used, but may be read as “water repellency,” “water-repellent film,” and “water-repellent member,” respectively assuming an aqueous ink. In addition, when the present disclosure is implemented, it is not necessarily required to limit the kind and applications of a liquid. The embodiments described below are examples, and for example, a detailed configuration may be appropriately changed and implemented by a person skilled in the art without departing from the spirit of the present disclosure.

In the drawings referred to in the description of the following embodiments and Examples, elements with the same reference symbols have the same functions unless otherwise stated. In addition, the description “XX or more and YY or less” or “from XX to YY” representing a numerical range means a numerical range including XX (lower limit) and YY (upper limit) that are end points unless otherwise stated. When the numerical ranges are described in stages, the upper limits and lower limits of the respective numerical ranges, and numerical values described in Examples may be arbitrarily combined.

The inventors of the present disclosure have made extensive investigations on the above-mentioned disadvantage. As a result, the inventors have found that an orifice plate including a liquid-repellent film excellent in ink resistance and sliding resistance is obtained by arranging, between a substrate and the liquid-repellent film, an underlying film containing a silicon atom and a carbon atom, and having a Si—O bond on a surface thereof. Thus, the inventors have completed the present disclosure. That is, in the present disclosure, the sliding durability of the orifice plate is improved by forming a siloxane bond (Si—O—Si bond) between the underlying film and the liquid-repellent film, and chemical stability is obtained by including a Si—C bond in the underlying film. Accordingly, according to the present disclosure, there can be achieved an orifice plate having formed thereon a liquid-repellent film excellent in durability, the film achieving both ink resistance and sliding resistance even in an ultra-thin film at a monomolecular layer level, and an ink jet head including the orifice plate. In the following description, there are descriptions of the embodiments by taking the orifice plate as an example, but the present disclosure is not limited to the orifice plate because the present disclosure is also applicable to a member or the like in which no ejection orifice is formed.

### <Ink Jet Head>

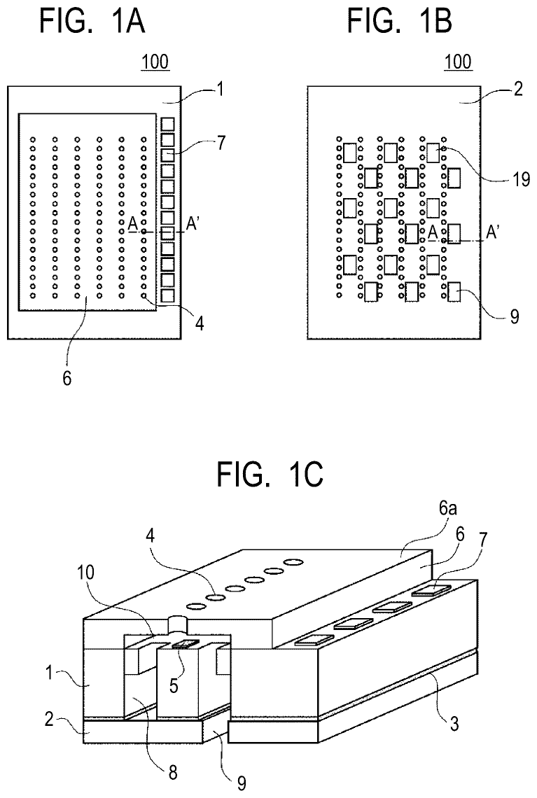

An ink jet head according to one embodiment of the present disclosure is an ink jet head including at least an orifice plate. The configuration of an ink jet head according to one embodiment of the present disclosure is described below with reference to the drawings. FIG. 1A is a top view of an ink jet head 100 according to one embodiment of the present disclosure. FIG. 1B is a bottom view of the ink jet head 100. In addition, FIG. 1C is a partial perspective view for illustrating a cross-sectional structure taken along the line A-A′ illustrated in each of FIG. 1A and FIG. 1B.

The ink jet head 100 includes a first flow path substrate 1, a second flow path substrate 2, an adhesive layer 3, ejection orifices 4, ejection energy-generating elements 5, an orifice plate 6, electrodes 7, and an ink tank chamber. The ink tank chamber is not shown in FIG. 1A to FIG. 1C. In addition, among the constituent components of the ink jet head, components that are not directly related to the present disclosure (e.g., an electric circuit and wiring) are not shown.

A set of the first flow path substrate 1 and the second flow path substrate 2, a set of the first flow path substrate 1 and the orifice plate 6, and a set of the first flow path substrate 1 and the ink tank chamber are each bonded to be integrated with each other via the adhesive layer 3 to form a flow path structure. In the flow path structure, a first through-flow path 8 and a second through-flow path 9 are formed and communicate to each other to form an ink supply path. In FIG. 1C, only part of the adhesive layer 3 is illustrated for the sake of convenience in illustration.

An ink is supplied from the ink tank chamber to a liquid flow path 10 through the second through-flow path 9 formed in each of the second flow path substrate 2 and the first flow path substrate 1. Then, the ink is ejected from the ejection orifices 4 after being given ejection energy by the ejection energy-generating elements 5. The ink that has not been ejected from the ejection orifices 4 flows back to the ink tank chamber through the first through-flow path 8 formed in the first flow path substrate 1 and a third through-flow path 19 (circulation return path) formed in the second flow path substrate 2.

Although the plurality of ejection orifices 4 are arranged in the orifice plate 6 (liquid-repellent member), an arrangement method (number and positions) for the ejection orifices 4 is not limited to the illustrated example. On the outer surface of the orifice plate 6, that is, an orifice surface 6a that is the surface of the orifice plate on a side opposite to the surface on which the liquid flow path 10 is formed, a liquid-repellent film containing a fluorine compound and the like to be described later is formed. On the first flow path substrate 1, the ejection energy-generating elements 5 for ejecting a liquid are arranged at positions corresponding to the respective ejection orifices 4, and the ejection energy-generating elements 5 are driven in response to an electric signal transmitted from outside via the electrodes 7. For example, electrothermal conversion elements or piezoelectric elements are suitably used as the ejection energy-generating elements 5.

### [Orifice Plate]

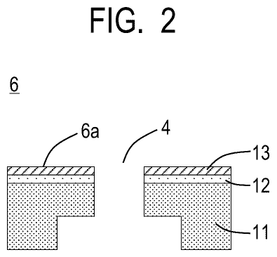

FIG. 2 is a schematic sectional view for illustrating a typical configuration of the orifice plate 6 having the ejection orifices 4. The orifice plate 6 includes: a substrate 11; a liquid-repellent film 13 formed on the outermost surface (orifice surface 6a) of the substrate on an ink ejection surface side; and an underlying film 12 formed between the substrate 11 and the liquid-repellent film 13.

### (Substrate)

Silicon is suitable as a material for forming the substrate 11 of the orifice plate 6. That is, the substrate 11 is preferably a silicon substrate. Silicon carbide, silicon nitride, various glasses, such as quartz glass and borosilicate glass, various ceramics, such as alumina and gallium arsenide, and resins such as polyimide may each be used as the substrate in addition to silicon.

### (Underlying Film)

In the present disclosure, the underlying film 12 is arranged between the substrate 11 and the liquid-repellent film 13 to be arranged on the outer surface (orifice surface 6a) of the orifice plate 6. The underlying film 12 contains at least a silicon atom (Si), a carbon atom (C), and an oxygen atom (O). In addition, the maximum peak P of the binding energy of the Si2p orbital of the surface part of the underlying film measured by X-ray photoelectron spectroscopy (XPS) falls within the range of 102.9 (eV)<P≤104.0 (eV). The term “surface part of the underlying film” means the surface of the underlying film on a side that is bonded to the liquid-repellent film by forming a siloxane bond. A large number of hydroxy groups (OH groups) are formed on the surface of the underlying film 12 having the above-mentioned characteristics, and the adhesiveness of the orifice plate is improved by forming a siloxane bond with a material for the liquid-repellent film 13 having a reactive silyl group. The improvement in adhesiveness leads to an improvement in sliding resistance of the orifice plate. In addition, the underlying film 12 itself is also in a chemically stable state because the underlying film contains a Si—C bond. As a result, an orifice plate excellent in ink resistance and sliding resistance can be obtained.

A thermal oxide film of silicon (not shown) is preferably formed in a lower layer (between the underlying film 12 and the substrate 11) of the underlying film. That is, the orifice plate according to the present disclosure may have such a configuration as “silicon substrate 11→thermal oxide film of silicon→underlying film 12→liquid-repellent film 13.” The thermal oxide film of silicon may be formed by, for example, thermal oxidation of the silicon substrate 11. The thickness of the thermal oxide film of silicon is about 100 nm.

It is not always required to arrange the thermal oxide film of silicon, but when the thermal oxide film is arranged, the adhesiveness and liquid resistance of the underlying film are further improved.

The binding energy of the Si2p orbital of the surface part of the underlying film measured by X-ray photoelectron spectroscopy is described below. The X-ray photoelectron spectroscopy is a method of obtaining a spectrum by irradiating the surface of a sample with an X-ray in an ultra-high vacuum and spectroscopically analyzing the kinetic energy of an inner-shell electron emitted by an external photoelectric effect. In the X-ray photoelectron spectroscopy, the binding energy between an electron before its emission and an atomic nucleus is calculated. The binding energy shows a value specific to an element, and a photoelectron emission amount increases or decreases in accordance with an element concentration in a measurement region. Accordingly, identification of the element and its chemical structure, and quantitative analysis can be performed based on this calculation result. Specifically, the measurement of the atomic composition ratios of elements present at a depth of several nanometers from the surface, the identification of the bonding state of each atom for forming a material, and the like can be performed.

Specifically, in the present disclosure, the maximum peak P of the binding energy of the Si2p orbital in the surface part of the underlying film may be measured by the following method. As a measurement device, for example, Quantera II (product name, manufactured by ULVAC-PHI, Inc.) may be used. AlKα is used as an X-ray source. In addition, measurement conditions are set as follows: analysis region: φ200 μm; pass energy: 140 eV; number of scans: 10; and detection angle: 45°.

Values of the maximum peak P (eV) of the binding energy of the Si2p orbital in accordance with a difference in Si bonding structure are shown in Table 1. As shown in Table 1, the maximum peak P of the binding energy of the Si2p orbital shows a specific range depending on a difference in bonding structure between Si and another element.

TABLE 1

| Bonding | |
|---|---|
| structure | Binding energy [eV] (Si2p) |
| —Si—Si— | 98.8 < P < 99.6 |
| —Si—C— | 99.6 ≤ P ≤ 101.9 |
| —Si—O—C— | 101.9 < P ≤ 102.9 |
| —Si—O— | 102.9 < P ≤ 104.0 |

The maximum peak P of the binding energy of the Si2p orbital resulting from a Si—O bond specified in the present disclosure shows a value within the range of 102.9 (eV)<P≤104.0 (eV). That is, when the P in the surface part of the underlying film falls within the above-mentioned range, it may be specified that the underlying film has a Si—O bond on its surface.

In addition, in the present disclosure, in terms of sliding resistance and ink resistance, the atomic composition ratios (atomic %) of the silicon atom, the carbon atom, and the oxygen atom included in the underlying film preferably fall within the following respective ranges. The atomic composition ratios may be determined by subjecting the underlying film to XPS analysis:
silicon atom: 19 atomic % to 26 atomic %;
carbon atom: 13 atomic % to 42 atomic %; and
oxygen atom: 39 atomic % to 61 atomic %.

### (Method of Forming Underlying Film)

The following two methods are given as methods of forming an underlying film containing a silicon atom, a carbon atom, and an oxygen atom, and having a Si—O bond on its surface. In the present disclosure, those methods may be appropriately selected and used.

The first method is a method involving forming a film containing a silicon atom, a carbon atom, and an oxygen atom by a chemical vapor deposition (CVD) method. Specifically, SiH, CH₄, and N₂O are used as raw materials, and a film is formed by high-frequency discharge plasma CVD. In addition, a film may be formed by using a known method such as a sputtering method.

The second method is a method involving: forming a film containing a silicon atom and a carbon atom by the CVD method; and then introducing an oxygen atom into the film. Specifically, first, a silicon carbide film (SiC film) containing a silicon atom and a carbon atom is formed by high-frequency discharge plasma CVD through use of SiH and CH₄ as raw materials. Next, an oxidation treatment film containing a silicon oxide is formed on the surface of the formed SiC film on a side in contact with the liquid-repellent film by subjecting the surface of the SiC film to surface treatment in an oxidizing atmosphere. An example of the silicon oxide is silicon dioxide (SiO₂). That is, according to the second method, there can be formed an underlying film including: a film containing silicon carbide; and an oxidation treatment film containing a silicon oxide on the surface of the film containing silicon carbide on the side in contact with the liquid-repellent film. The surface treatment may be performed by a method of oxidizing a surface selected from, for example, UV ozone and oxygen plasma ashing. The time period for which the surface treatment is performed only needs to be appropriately set, and may be set to, for example, from 1 minute to 30 minutes. In the course of an investigation made by the inventors of the present disclosure, it has been found that the amount of reactive groups (OH groups) on the outermost surface (surface having the liquid-repellent film formed thereon) of the underlying film can be increased by performing the surface treatment in an oxidizing atmosphere. The SiC film may be formed by using a known method such as a sputtering method. Further, the amount of OH groups on the surface may be increased by treating the surface of the underlying film formed by the first method in an oxidizing atmosphere.

A silicon substrate is generally used as the substrate serving as the lower layer of the underlying film. In addition, as described above, a thermal oxide film of silicon may be formed on the surface of the silicon substrate on an underlying film side. The thickness of the underlying film is preferably 10 nm or more, more preferably 50 nm or more from the viewpoint of protecting silicon from an ink. In addition, the thickness of the underlying film is preferably 300 nm or less, more preferably 200 nm or less from the viewpoint of suppressing cohesive failure at the time of sliding. The thickness of the underlying film does not include the thickness of the oxidation treatment film containing the silicon oxide described above.

The underlying film containing a silicon atom, a carbon atom, and an oxygen atom, which is formed as described above, itself has chemical stability resulting from a Si—C bond while including a OH group on its surface. Accordingly, when a liquid-repellent film is formed on the underlying film, a siloxane bond is formed by a silane coupling reaction between a OH group of the underlying film and a reactive silyl group of the liquid-repellent film, and hence a film excellent in ink resistance and sliding resistance can be achieved.

### (Liquid-Repellent Film)

As a liquid-repellent material for forming the liquid-repellent film 13, a fluorine-based material and a silicone-based material are known. As the fluorine-based material, there may be used a fluorine compound, which has a linear main chain structure, and in which only one end out of both the ends of the main chain forms a chemical bond (Si—O—Si bond) with a OH group on the surface of the underlying film. Specifically, there is given a fluorine compound having at least one reactive silyl group represented by the following structural formula (1) at only one end of its main chain in order to form a Si—O—Si bond. When the fluorine compound has a reactive silyl group at only one end thereof, a reaction between molecules of the fluorine compound can be suppressed.

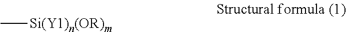

In the structural formula (1), Y1 represents a group selected from an alkyl group, a chloro group, and a bromo group, R represents a hydrogen atom or an alkyl group, “n” and “m” each represent an integer of from 0 to 3, and n+m=3 is satisfied.

In addition, the fluorine compound preferably has a CF₃ structure (CF₃ group) at the other end of its main chain. This is because the CF₃ structure has small surface free energy and hence can express high liquid repellency.

The main chain structure of the fluorine compound preferably has a perfluoropolyether (hereinafter sometimes referred to as “PFPE”) structure from the viewpoint of ensuring liquid repellency and sliding resistance. The PFPE structure preferably has one or more structures selected from repeating structures represented by the following structural formulae (2) to (5). In the following structural formulae (2) to (5), n1 to n4 each represent an integer of 1 or more.

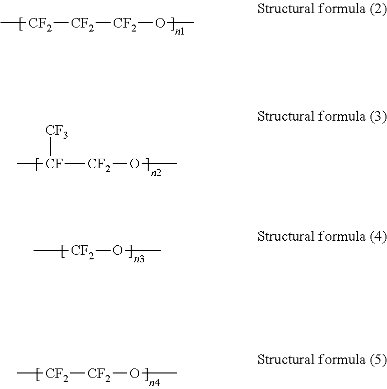

Preferred specific examples of the fluorine compound include compounds represented by the following structural formulae (6) to (8). In the structural formula (6), “p”, “q”, and “r” each represent an integer of 1 or more. In the structural formula (7), “s” and “t” each represent an integer of 1 or more. In the structural formula (8), “u” represents an integer of 1 or more.

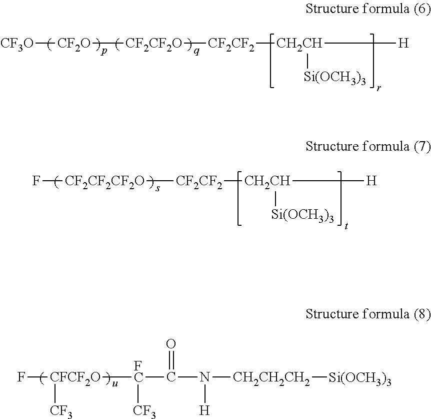

As commercially available fluorine-based materials each having a PFPE structure in its main chain and each having a reactive silyl group at only one end of the main chain, there may be given, for example, OPTOOL DSX (product name, manufactured by Daikin Industries, Ltd.), X-71-195 and KY-1908 (product names, manufactured by Shin-Etsu Chemical Co., Ltd.), and SC100 (product name, manufactured by Canon Optron, Inc.). In addition, instead of the above-mentioned fluorine-based materials, for example, OR-510 (product name, manufactured by Canon Optron, Inc.), which is a non-fluorine-based material, may also be used.

### (Method of Forming Liquid-Repellent Film)

Next, a method of forming the liquid-repellent film 13 on the underlying film 12 containing a silicon atom, a carbon atom, and an oxygen atom is described. The liquid-repellent film may be formed by subjecting the underlying film to silane coupling treatment with, for example, the above-mentioned fluorine compound. Specifically, first, the fluorine compound is applied to the surface of the underlying film 12 having a OH group formed thereon. There is no particular limitation on a method for the application, and examples thereof may include a vacuum vapor deposition method, a thermal vapor deposition method, a spray coating method, a spin coating method, and a dip coating method. Subsequently, the reactive silyl group (alkoxysilyl group or halogenated silyl group) at an end of the fluorine compound is hydrolyzed to be converted to a silanol group (Si—OH group). When a dehydration condensation reaction (silane coupling) is performed between the resultant Si—OH group and a OH group formed on the underlying film 12, the liquid-repellent film 13 having a Si—O—Si bond formed with the underlying film is obtained. The thickness of the liquid-repellent film is not particularly limited, but may be set to, for example, from 10 nm to 50 nm.

The hydrolysis of the reactive silyl group at the end of the fluorine compound is caused by exposing the fluorine compound to moisture. In addition, the hydrolysis is also caused by bringing the fluorine compound into contact with adsorbed water that is present on the surface of the underlying film. The above-mentioned dehydration condensation reaction proceeds even at room temperature, but may be accelerated by performing the reaction at high temperature (e.g., from 100° C. to 120° C.). The reaction time of the dehydration condensation reaction may be appropriately selected in accordance with the reaction temperature. For example, the reaction time of the reaction performed at room temperature is about 10 hours, and the reaction time of the reaction performed at 120° C. is about 1 hour.

After the dehydration condensation reaction is performed, washing is performed to remove the remaining unbonded fluorine compound. There is no particular limitation on a method for the washing, but an example thereof is a method involving immersing the orifice plate 6 in a fluorine solvent that is compatible with the fluorine compound. At this time, the washing only needs to be performed to such an extent that it is visually observed that no fluorine compound remains on the underlying film. Finally, the drying of the fluorine solvent provides the orifice plate 6 including the liquid-repellent film 13 arranged on the underlying film 12 on the substrate 11.

### <Method of Producing Ink Jet Head>

A method of producing an ink jet head according to the present disclosure is a method of producing an ink jet head having such a configuration as described above, and includes the following steps: forming a substrate having an ejection orifice configured to eject an ink; forming an underlying film on the ink ejection surface side of the substrate, the underlying film containing a silicon atom (Si), a carbon atom (C), and an oxygen atom (O), and the underlying film having a maximum peak P of the binding energy of the Si2p orbital of its surface part measured by X-ray photoelectron spectroscopy falling within the range of 102.9 (eV)<P≤104.0 (eV); and forming a liquid-repellent film on the ink ejection surface side of the underlying film. The atomic composition ratios (atomic %) of the silicon atom, the carbon atom, and the oxygen atom included in the underlying film preferably fall within the following respective ranges:
silicon atom: 19 atomic % to 26 atomic %;
carbon atom: 13 atomic % to 42 atomic %; and
oxygen atom: 39 atomic % to 61 atomic %.

In addition, the step of forming the underlying film preferably includes the steps of: forming a film containing a silicon atom and a carbon atom; and subjecting the formed film to surface treatment in an oxidizing atmosphere using, for example, UV ozone or oxygen plasma ashing. For details about the above-mentioned respective steps, reference may be appropriately made to the description of the ink jet head according to the present disclosure described above.

### <Liquid-Repellent Substrate>

A liquid-repellent substrate according to the present disclosure includes a substrate, a liquid-repellent film, and an underlying film arranged between the substrate and the liquid-repellent film. The liquid-repellent film forms a siloxane bond with the underlying film by silane coupling. In addition, the underlying film contains a silicon atom (Si), a carbon atom (C), and an oxygen atom (O), and the maximum peak P of the binding energy of the Si2p orbital of its surface part measured by the X-ray photoelectron spectroscopy falls within the range of 102.9 (eV)<P≤104.0 (eV). For other details about the liquid-repellent substrate, reference may be appropriately made to the description of the ink jet head according to the present disclosure described above.

### EXAMPLES

The present disclosure is described below by way of specific Examples and Comparative Examples.

### Example 1

### (1) Preparation of Substrate

A silicon substrate having a thickness of 725 μm and having an ejection orifice formed therein was prepared as a substrate.

### (2) Formation of Underlying Film

Next, a silicon carbide (SiC) film was laminated to a thickness of 50 nm on the silicon substrate with a CVD film-forming device. A gas containing 20 sccm of SiH and 450 sccm of CH₄ was used as a raw material, and a film forming temperature was set to 60° C.

### (3) Surface Treatment

Next, an oxidation treatment film containing SiO₂ was formed on the surface of the SiC film by subjecting the silicon substrate having the SiC film formed thereon as an underlying film to surface treatment for 6 minutes with a UV ozone device. Thus, an underlying film containing a silicon atom, an oxygen atom, and a carbon atom was formed on the silicon substrate.

### (Evaluation (1): Analysis of Underlying Film)

The produced underlying film was subjected to XPS analysis under the following conditions.
Measurement device: Quantera II (product name), manufactured by ULVAC-PHI, Inc.
X-ray source: AlKα
Analysis region: φ200 μm
Pass energy: 140 eV
Number of scans: 10
Detection angle: 45°

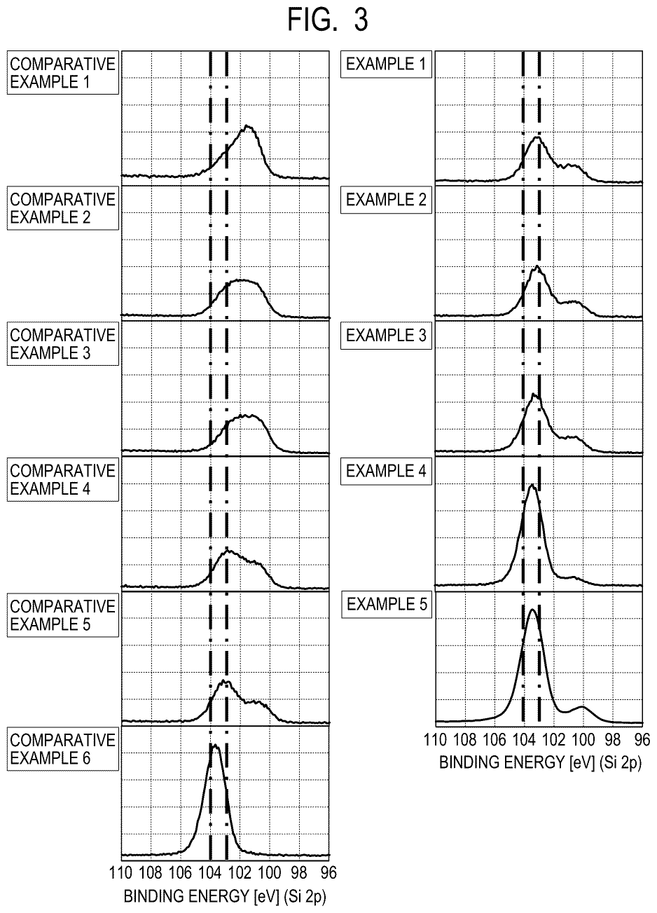

The XPS spectrum of the resultant underlying film is shown in FIG. 3. The maximum peak P of the binding energy of the Si2p orbital of the underlying film was 103.0 (eV), and hence it was recognized that the underlying film had a Si—O bond on its surface. In addition, as shown in Table 2, an atomic composition ratio (atomic %) among the silicon atom (Si), the carbon atom (C), and the oxygen atom (O) in the underlying film was 19:42:39.

### (4) Formation of Liquid-Repellent Film

Subsequently, the silicon substrate in which the surface of the underlying film has been treated was placed in a vacuum vapor deposition machine, and a fluorine compound was deposited from the vapor on the surface of the silicon substrate having the underlying film formed thereon. A compound having an average molecular weight of 5,000 and represented by the structural formula (6) (product name: X-71-195F, manufactured by Shin-Etsu Chemical Co., Ltd.) was used as the fluorine compound. The vapor deposition was performed in such a manner that 160 mg of the fluorine compound in a state of being impregnated into steel wool was placed in a copper container and the fluorine compound was heated on a resistance boat. Subsequently, the silicon substrate having the fluorine compound deposited from the vapor thereon was placed in an oven, and was allowed to stand still for 45 minutes under an environment at 120° C.

### (5) Surface Washing

Subsequently, the silicon substrate taken out from the oven was washed by immersion in a fluorine solvent for 30 seconds so that the fluorine compound adhering to its surface was removed. Finally, an orifice plate including the underlying film and the liquid-repellent film (16 nm) on the substrate was produced by drying the fluorine solvent. The XPS spectrum of the produced underlying film is shown in FIG. 3. In addition, the analysis results of the underlying film are shown in Table 2.

### Examples 2 to 4 and Comparative Examples 1 to 5

An orifice plate according to each of Examples and Comparative Examples was produced through the formation of an underlying film and a liquid-repellent film by the same method as that in Example 1 except that the conditions for (3) Surface Treatment were changed as shown in Table 2. The XPS spectra of the produced underlying films are shown in FIG. 3. In addition, the analysis results of the underlying films are shown in Table 2.

### Example 5

An orifice plate according to Example 5 was produced through the formation of an underlying film and a liquid-repellent film by the same method as that in Example 1 except that the conditions for (3) Surface Treatment were changed as described below.

The silicon substrate having the SiC film formed thereon as an underlying film was placed in a chamber of a plasma treatment device, and the surface of the underlying film was treated. Specifically, after the inside of the chamber was evacuated, only an oxygen atom was introduced. Then, plasma was generated by setting an energy to 1,000 eV, and a bias was applied to accelerate the plasma (output power value: 120 W). This state was maintained for 300 seconds. The XPS spectrum of the underlying film is shown in FIG. 3. In addition, the analysis results of the underlying film are shown in Table 2. As shown in Table 2, the analysis results of the underlying film were substantially the same as those of Example 4.

### Comparative Example 6

An orifice plate according to Comparative Example 6 was produced through the formation of a liquid-repellent film by the same method as that in Example 1 on a silicon thermal oxide film (th-SiO₂) substrate formed by the thermal oxidation of a silicon substrate. The XPS spectrum of the underlying film is shown in FIG. 3. In addition, the analysis results of the underlying film are shown in Table 2.

Subsequently, the evaluations of the sliding resistance and ink resistance of each of the produced liquid-repellent films are described.

### (Evaluation (2): Evaluation of Sliding Resistance)

The sliding resistance of each of the produced liquid-repellent films was evaluated by the following procedure. A high-density felt material (product name: CS-7, manufactured by Taber Industries) serving as a sliding material was attached to a friction and wear tester (product name: FPR-2100, manufactured by Rhesca Co., Ltd.), and a reciprocating sliding test was performed on the liquid-repellent film under the following conditions: sliding load: 650 g, sliding width: 10 mm, linear velocity: 50.8 mm/sec, and number of sliding cycles: 15,000. The contact angle of the liquid-repellent film after the sliding was measured by the following method.

A dynamic receding contact angle θr (°) with respect to pure water was measured with a micro contact angle meter (product name: DropMeasure, manufactured by Microjet Corporation). In order to satisfy practicality as a liquid-repellent film, the Or needs to be 90° or more. Evaluation criteria are as described below. The results are shown in Table 2.

∘: θr was 90° or more.

x: θr was less than 90°.

### (Evaluation (3): Evaluation of Ink Resistance)

The ink resistance of each of the liquid-repellent films produced in Examples 1 to 5 and Comparative Example 6 was evaluated by the following procedure. An alkaline dye ink (product name: BCI-7C, manufactured by CANON KABUSHIKI KAISHA) was used as an ink. The above-mentioned ink was placed in a PFA container. The liquid-repellent film was immersed in the ink so that the entire liquid-repellent film was brought into contact with the ink, followed by the sealing of the container with a lid. The container was placed in an oven in this state, and was maintained at a temperature of 60° C. for 1 week. The taken-out liquid-repellent film was thoroughly washed with water so that the ink was removed. Then, a dynamic receding contact angle θr (°) with respect to pure water was measured by the same method as that described above. Evaluation criteria are as described below. The results are shown in Table 2 (Table 2-1 and Table 2-2).

∘: θr was 90° or more.

x: θr was less than 90°.

TABLE 2-1

| | | Underlying film | | |
|---|---|---|---|---|
| | Substrate | Formation | Underlying | |
| | Material | method | film | Surface treatment |
| Comparative Example 1 | Silicon | CVD | SiC | — |
| Comparative Example 2 | Silicon | CVD | SiC | UV ozone: 1 minute |
| Comparative Example 3 | Silicon | CVD | SiC | UV ozone: 2 minutes |
| Comparative Example 4 | Silicon | CVD | SiC | UV ozone: 3 minutes |
| Comparative Example 5 | Silicon | CVD | SiC | UV ozone: 4 minutes |
| Example 1 | Silicon | CVD | SiC | UV ozone: 6 minutes |
| Example 2 | Silicon | CVD | SiC | UV ozone: 8 minutes |
| Example 3 | Silicon | CVD | SiC | UV ozone: 10 minutes |
| Example 4 | Silicon | CVD | SiC | UV ozone: 30 minutes |
| Example 5 | Silicon | CVD | SiC | Oxygen plasma ashing: |
| | | | | 5 minutes |
| Comparative Example 6 | Silicon | Thermal | th-SiO₂ | — |
| | | oxidation | | |

TABLE 2-2

| | Underlying film | | | | Liquid-repellent film | | |
|---|---|---|---|---|---|---|---|
| | Atomic composition | | | XPS | | Evaluation | |
| | ratio (atomic %) | | | P | | Sliding | Ink |
| | Si | C | O | (eV) | Material | resistance | resistance |
| Comparative Example 1 | 35 | 63 | 1 | 101.3 | x-71-195 | x | — |
| Comparative Example 2 | 23 | 49 | 28 | 101.6 | x-71-195 | x | — |
| Comparative Example 3 | 22 | 50 | 28 | 101.9 | x-71-195 | x | — |
| Comparative Example 4 | 21 | 44 | 35 | 102.7 | x-71-195 | x | — |
| Comparative Example 5 | 20 | 43 | 37 | 102.8 | x-71-195 | x | — |
| Example 1 | 19 | 42 | 39 | 103.0 | x-71-195 | ○ | ○ |
| Example 2 | 20 | 39 | 41 | 103.2 | x-71-195 | ○ | ○ |
| Example 3 | 22 | 32 | 46 | 103.3 | x-71-195 | ○ | ○ |
| Example 4 | 26 | 13 | 61 | 103.4 | x-71-195 | ○ | ○ |
| Example 5 | 26 | 13 | 61 | 103.4 | x-71-195 | ○ | ○ |
| Comparative Example 6 | 33 | 0 | 67 | 103.8 | x-71-195 | ○ | x |

As shown in Table 2, the dynamic receding contact angle θr of each of the liquid-repellent films according to Examples 1 to 5 was 90° or more in both the evaluation of sliding resistance and the evaluation of ink resistance. Meanwhile, the dynamic receding contact angle θr of the liquid-repellent film according to Comparative Example 6 was 90° or more in the evaluation of sliding resistance, but the dynamic receding contact angle θr was less than 90° in the evaluation of ink resistance. Accordingly, it can be said that the liquid-repellent films according to Examples 1 to 5 each have excellent practical characteristics in terms of both sliding resistance and ink resistance.

According to the present disclosure, there can be provided a liquid-repellent substrate and an ink jet head each including a liquid-repellent film excellent in sliding resistance and ink resistance.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-225101, filed Dec. 20, 2024, which is hereby incorporated by reference herein in its entirety.

What is claimed is:

1. An ink jet head comprising:
an orifice plate including:
a substrate;
a liquid-repellent film formed on an outermost surface of the substrate on an ink ejection surface side; and
an underlying film formed between the substrate and the liquid-repellent film,
wherein the underlying film contains a silicon atom (Si), a carbon atom (C), and an oxygen atom (O),
wherein the liquid-repellent film forms a siloxane bond with the underlying film, and
wherein a maximum peak P of a binding energy of a Si2p orbital of a surface part of the underlying film measured by X-ray photoelectron spectroscopy satisfies formula (1):
$$102.9 ( eV ) < P \leq 104. ( eV ) . \qquad ( 1 )$$

2. The ink jet head according to claim 1,
wherein an atomic composition ratio of the silicon atom in the underlying film is 19 atomic % to 26 atomic %,
wherein an atomic composition ratio of the carbon atom included in the underlying film is 13 atomic % to 42 atomic %, and
wherein an atomic composition ratio of the oxygen atom included in the underlying film is 39 atomic % to 61 atomic %.

3. The ink jet head according to claim 1, wherein the underlying film contains silicon carbide.

4. The ink jet head according to claim 1, wherein the underlying film has a thickness of 10 nm or more and 300 nm or less.

5. The ink jet head according to claim 1, wherein a thermal oxide film of silicon is formed in a lower layer of the underlying film.

6. The ink jet head according to claim 1, wherein the substrate is a silicon substrate.

7. A method of producing an ink jet head comprising:
forming a substrate having an ejection orifice configured to eject an ink;
forming an underlying film on an ink ejection surface side of the substrate, the underlying film containing a silicon atom (Si), a carbon atom (C), and an oxygen atom (O); and
forming a liquid-repellent film on an ink ejection surface side of the underlying film,
wherein an atomic composition ratio of the silicon atom in the underlying film is 19 atomic % to 26 atomic %,
wherein an atomic composition ratio of the carbon atom included in the underlying film is 13 atomic % to 42 atomic %,
wherein an atomic composition ratio of the oxygen atom included in the underlying film is 39 atomic % to 61 atomic %, and
wherein the underlying film having a maximum peak P of a binding energy of a Si2p orbital of a surface part thereof measured by X-ray photoelectron spectroscopy satisfies formula (1):
$$102.9 ( eV ) < P \leq 104. ( eV ) . \qquad ( 1 )$$

8. The method of producing an ink jet head according to claim 7, wherein the underlying film is formed by using one of a chemical vapor deposition (CVD) method or a sputtering method.

9. The method of producing an ink jet head according to claim 7, wherein the forming the underlying film comprises:
forming a film containing the silicon atom and the carbon atom; and
subjecting the formed film to surface treatment using UV ozone or oxygen plasma ashing.

10. A liquid-repellent substrate comprising:
a substrate;
a liquid-repellent film; and
an underlying film arranged between the substrate and the liquid-repellent film,
wherein the liquid-repellent film forms a siloxane bond with the underlying film, and
wherein the underlying film contains a silicon atom (Si), a carbon atom (C), and an oxygen atom (O), and a maximum peak P of a binding energy of a Si2p orbital of a surface part of the underlying film measured by X-ray photoelectron spectroscopy satisfies formula (1):
$$102.9 ( eV ) < P \leq 104. ( eV ) . \qquad ( 1 )$$

11. The liquid-repellent substrate according to claim 10,
wherein an atomic composition ratio of the silicon atom in the underlying film is 19 atomic % to 26 atomic %,
wherein an atomic composition ratio of the carbon atom included in the underlying film is 13 atomic % to 42 atomic %, and
wherein an atomic composition ratio of the oxygen atom included in the underlying film is 39 atomic % to 61 atomic %.

12. The liquid-repellent substrate according to claim 10, wherein the underlying film contains silicon carbide.

13. The liquid-repellent substrate according to claim 10, wherein the underlying film has a thickness of 10 nm or more and 300 nm or less.

14. The liquid-repellent substrate according to claim 10, wherein a thermal oxide film of silicon is formed in a lower layer of the underlying film.

15. The liquid-repellent substrate according to claim 10, wherein the substrate is a silicon substrate.
